(19) United States
(12) Patent Application Publication
(10) Pub. No.: US 2025/0174216 A1
(43) Pub. Date: May 29, 2025

(54) SYSTEMS AND METHODS FOR MODIFYING MUSICAL SIGNALS

(71) Applicant: Fender Musical Instruments Corporation, Los Angeles, CA (US)

(72) Inventors: Charles ADAMS, Gilbert, AZ (US); Henry WONG, Tempe, AZ (US); Christopher Wallace BALDWIN, Mesa, AZ (US); Kenneth William PORTER, Scottsdale, AZ (US)

(73) Assignee: Fender Musical Instruments Corporation, Los Angeles, CA (US)

(21) Appl. No.: 18/521,485

(22) Filed: Nov. 28, 2023

(51) Int. Cl. G10H 1/055; G05G 1/01; G05G 1/02; G05G 1/10; G05G 5/03

(52) U.S. Cl. CPC G10H 1/0553; G05G 1/01; G05G 1/02; G05G 1/10; G05G 5/03

(57) ABSTRACT

Described herein are systems and methods for modifying musical signals. An exemplary system for modifying musical signals has at least one non-contact switch. The non-contact switch includes an actuator that translates and rotates when pushed and turned, respectively, by a user. A sensor, such as a magnetic field sensor, an optical sensor, an AC induction sensor, or another non-contact sensing device, senses the position of the actuator, which may include both translational position and rotational position. Modification of the musical signals may be based on the position of the actuator. No physical contact between the actuator and the sensor is required during operation of the non-contact switch. Accordingly, the forces generated during the pushing and turning of the non-contact switch are applied to the non-contact switch, while the sensor and other components within the effects unit are isolated from the forces.

### FIELD

The present invention relates generally to musical equipment, and more specifically, to effects units for modifying musical signals.

### BACKGROUND

Musical effects units, also known as “pedalboards,” “multi-effects pedals,” “multi-effects processors,” and “foot switches,” are external devices used to modify the sound of musical instruments such as electric guitars. They are commonly used by musicians to alter the sounds produced by instruments in real-time, including, but not limited to, altering the pitch and/or amplitude, and/or adding distortion and/or reverberation. Music of various musical genres is produced using effects units to achieve a distinctive musical signature.

Conventional effects units include mechanical switches with knobs for adjusting the settings of the effects units and/or modifying sounds received from instruments. The mechanical switches are often housed in a pedal-shaped housing. The mechanical switches may be pressed and/or turned to adjust the settings. For example, the mechanical switches may be pushed down by foot (e.g., a foot switch) during a performance while the musician's hands are occupied by playing the instrument. However, the application of large forces to the mechanical switches (e.g., when the musician stomps down on the switches) may damage delicate electronics circuitry housed within the effects units. Furthermore, the pressing and turning of the mechanical switches may cause the internal components of the switches to make contact with each other, leading to wear and eventual failure of the components.

### SUMMARY

According to various embodiments, an apparatus for modifying musical signals has at least one non-contact switch. The non-contact switch includes an actuator that translates and rotates when pushed and turned, respectively, by a user. A sensor, such as a magnetic field sensor, an optical sensor, an AC induction sensor, or another non-contact sensing device, senses the position of the actuator, which may include both translational position (also referred to herein as “linear position”) and rotational position (also referred to herein as “angular position”). Modification of the musical signals may be based on the position of the actuator. No physical contact between the actuator and the sensor is required during operation of the non-contact switch. Accordingly, the forces generated during the pushing and turning of the non-contact switch are applied to the non-contact switch, while the sensor and other components within the effects unit are isolated from the forces. Such an apparatus can thus provide for a more reliable switch design that is slower to wear down than conventional mechanical switch designs, and as such, the apparatus may have a longer operational lifespan than conventional effects units.

According to various embodiments, an apparatus for modifying at least one musical signal includes a housing, at least one input for receiving at least one musical signal generated at least in part by at least one musical instrument, at least one processor for modifying the at least one musical signal, and at least one non-contact switch mounted to the housing such that a user can interact with the at least one non-contact switch to adjust the modification of the at least one musical signal. The at least one non-contact switch includes an actuator configured to rotate about an axis and translate along the axis, and a sensor configured to generate at least one measurement corresponding to a position of the actuator, wherein the at least one processor is configured to modify the at least one musical signal based on the measurement corresponding to the position of the actuator.

In any of these embodiments, the sensor may include a magnetic sensor, an optical sensor, or an AC induction sensor. For example, the sensor may include magnetic field sensor, and the actuator may include a magnet. The magnet may be diametrically magnetized such that the rotation of the actuator about the axis changes a direction of the magnetic field associated with the magnet. The translation of the actuator along the axis may change a distance between the actuator and the sensor.

In any of these embodiments, the position of the actuator may include one or both of a translational position and an angular position. In various embodiments, the at least one measurement may include a measurement of the translational position and a measurement of the angular position.

In any of these embodiments, the at least one non-contact switch may include multiple non-contact switches. Each non-contact switch may include a switch body mounted to a housing of the apparatus and a sensor mounted to a PCB mounted beneath the switch bodies, such that multiple sensors are mounted to the same PCB. The multiple non-contact switches may be configured to modify multiple attributes of the at least one musical signal.

In any of these embodiments, the at least one processor may be configured to modify the at least one musical signal based on at least one of: a translational position of the actuator along the axis relative to at least one translational threshold, a translational speed of the actuator along the axis, a translational acceleration of the actuator along the axis, an angular position of the actuator about the axis relative to at least one angular threshold, a change in angle of the actuator about the axis, a rate of rotation of the actuator about the axis, and an angular acceleration of the actuator about the axis.

In any of these embodiments, the at least one non-contact switch may further include a light pipe surrounding at least a portion of the actuator. The at least one non-contact switch may further comprise at least one detent mechanism configured to provide tactile feedback to the user during one or both of the rotation of the actuator about the axis and the translation of the actuator along the axis. The at least one non-contact switch may further comprise at least one limiter configured to restrict the rotation of the actuator to a predetermined range of angles.

In any of these embodiments, the at least one processor may be configured to change a mode of operation of the apparatus. For example, in a first mode, the at least one processor may be configured to set at least one parameter based on the at least one measurement, and in a second mode, the at least one processor may be configured to modify the at least one musical signal based on the at least one parameter.

According to various embodiments, a method for modifying at least one musical signal includes: receiving, at an apparatus, at least one musical signal generated at least in part by at least one musical instrument; receiving, at a non-contact switch of the apparatus, a user input comprising at least one of a translation of an actuator of the non-contact switch along an axis and a rotation of the actuator about the axis such that the actuator of the non-contact switch moves relative to a sensor of the non-contact switch; generating, by the sensor, at least one measurement corresponding to a position of the actuator; and modifying, by at least one processor of the apparatus, the at least one musical signal based on the at least one measurement corresponding to the position of the actuator.

In any of these embodiments, modifying the at least one musical signal may include setting at least one parameter based on the at least one measurement and/or modifying the at least one musical signal based on the at least one parameter. The at least one parameter may be set in a first mode, and the at least one musical signal may be modified in a second mode. In various embodiments, during the second mode, a first user input to the non-contact switch may not change the at least one parameter of the apparatus. The first user input to the non-contact switch may be the rotation of the actuator. In various embodiments, during the second mode, a second user input to the non-contact switch may change the at least one parameter of the apparatus. The second user input to the non-contact switch may be the translation of the actuator.

In any of these embodiments, modifying the at least one musical signal may involve producing one or more special effects, including one or more of: overdrive, fuzz, wah, delay, buffer, chorus, flanger, phaser, tremolo, looper, compressor, octave, equalization, noise gate, acoustic, tuner, boost, pitch change, amplitude change, distortion, modulation, reverberation, delay, and repetition.

### BRIEF DESCRIPTION OF THE DRAWINGS

The invention will now be described, by way of example only, with reference to the accompanying drawings, in which:

FIG. 1 illustrates a perspective view of an exemplary apparatus for modifying musical signals, according to examples of the disclosure.

FIGS. 2A and 2B illustrate cross-sectional views of an exemplary non-contact switch of an apparatus for modifying musical signals, according to examples of the disclosure. FIG. 2A illustrates the exemplary non-contact switch in a default translational position and FIG. 2B illustrates the exemplary non-contact switch after it has been linearly translated relative to the default translational position.

FIGS. 3A and 3B illustrate top-down views of an exemplary processor board of an apparatus for modifying musical signals, according to examples of the disclosure. FIG. 3A illustrates an exemplary plurality of non-contact switches in a first angular position and FIG. 3B illustrates an exemplary non-contact switch of the plurality of non-contact switches after it has been rotated relative to the first angular position.

FIG. 4A illustrates a cross-sectional view of an exemplary non-contact switch of an apparatus for modifying musical signals, the exemplary non-contact switch having a detent mechanism, according to examples of the disclosure.

FIG. 4B illustrates a top-down view of an exemplary non-contact switch of an apparatus for modifying musical signals, the exemplary non-contact switch having a rotational limiter mechanism, according to examples of the disclosure.

FIG. 5 illustrates a block diagram of an exemplary apparatus for modifying musical signals, according to examples of the disclosure.

FIG. 6 illustrates a flowchart of an exemplary method for modifying musical signals, according to examples of the disclosure.

### DETAILED DESCRIPTION

Described herein, according to various embodiments, are examples of an apparatus for modifying musical signals based on the position of an actuator relative to a sensor. The apparatus can be, for example, a musical effects unit, pedalboard, multi-effects pedal, multi-effects processor, and/or foot switch. The apparatus can be used by a musician to alter the sound of one or more instruments as they are being played. For example, the user may connect a guitar to the apparatus, and the apparatus may apply effects (e.g., reverberation) to the musical signal generated by the guitar. To determine how the sound of the musical signal should be altered, the apparatus may rely on user inputs via one or more non-contact switches. The switches may be pushed and/or turning by the user. In some embodiments, the pushing of a switch may change the mode of the apparatus. For example, when the switch is pushed by a user, the switch may change from “on” mode to “off” mode, and the musical signal will no longer be modified. In some embodiments, the turning of the switch may be used to set the types and characteristics of the effect to be applied to the musical signal. For example, when the switch is rotated by a user, the type of effect may be changed from “reverberation” to “distortion.” In some embodiments, the turning of the switch may be used to change the parameter value of a musical signal. For example, when the switch is rotated by a user, the “delay time” can be increased or decreased. This may be done before the instrument is played in order to preset the desired characteristics of the effect.

In some embodiments, the switches include at least one non-contact switch. The non-contact switch can include a movable actuator and a fixed sensor, or vice versa. As the switch is pushed by the user, the actuator may move relative to the sensor. The sensor may be configured to measure the position of the actuator. Based on the translational position and/or rotational position of the actuator, at least one processor of the apparatus may modify the musical signals. The actuator and sensor do not physically contact each other during operation of the switch. This provides for a more reliable switch design that does not experience the wear experience by conventional mechanical switches, and as such, the apparatus may have a longer operational lifespan than conventional effects units.

According to various embodiments, the apparatus may include multiple non-contact switches, each switch comprising a switch body mounted to a housing of the apparatus. The actuator of each switch may be supported by the switch body such that it may move through and rotate within the switch body in a desired alignment, without changing its axis of rotation and translation. Beneath the switch bodies, a printed circuit board (PCB) may be mounted to the housing. The PCB may be electronically connected to various components of the apparatus, such as the sensors, which may be mounted beneath the switch bodies on the PCB. As each switch's actuator moves relative to its corresponding sensor, the measurements from the sensor may be received by the PCB. The multiple switches may be used to modify multiple attributes of the musical signals received by the apparatus.

In an exemplary embodiment, the actuator of a non-contact switch may include a magnet, and the sensor may include a magnetic field sensor. The magnetic field sensor may be configured to determine the position of the actuator based on the magnetic field characteristics of the magnet. As the switch is pushed, the magnet may move toward the magnetic field sensor, increasing the magnitude of the magnetic field measured by the sensor. According to various embodiments, the magnet may be diametrically magnetized such that the rotation of the switch changes the magnetic field associated with the magnet. For example, as the switch is turned, the poles of the magnet may rotate, changing the direction of the magnetic field measured by the sensor. Based on the position of the actuator, as determined by the magnetic field characteristics detected by the magnetic field sensor, the apparatus may modify the musical signals.

In the following description of the disclosure and embodiments, reference is made to the accompanying drawings in which are shown, by way of illustration, specific embodiments that can be practiced. It is to be understood that other embodiments and examples can be practiced and changes can be made without departing from the scope of the disclosure.

In addition, it is also to be understood that the singular forms “a,” “an,” and “the” used in the following description are intended to include the plural forms as well, unless the context clearly indicates otherwise. It is also to be understood that the term “and/or” as used herein refers to and encompasses any and all possible combinations of one or more of the associated listed items. It is further to be understood that the terms “includes, “including,” “comprises,” and/or “comprising,” when used herein, specify the presence of stated features, integers, steps, operations, elements, components, and/or units, but do not preclude the presence or addition of one or more other features, integers, steps, operations, elements, components, units, and/or groups thereof.

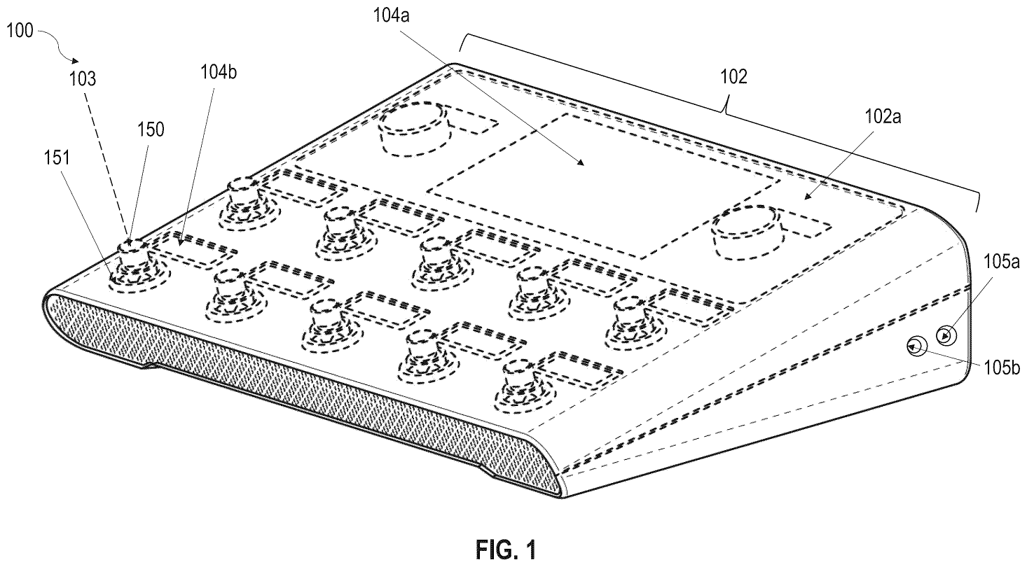

FIG. 1 illustrates a perspective view of an exemplary apparatus 100 for modifying musical signals. The apparatus 100 may be a musical effects unit, pedalboard, multi-effects pedal, multi-effects processor, and/or foot switch. The apparatus 100 may be used to modify musical signals generated, at least in part, by a musical instrument (e.g., an electric guitar). To do this, the apparatus 100 may receive the musical signals, modify the musical signals based on at least one input from a user, and output the modified musical signals to a speaker or other output device. In some embodiments, the apparatus 100 can include at least one non-contact switch 150, which includes an actuator. As discussed further below, as the switch 150 is operated (e.g., rotated or pushed) by the user, the actuator may move relative to a sensor of the switch 150 that is configured to determine the position (translational and/or rotational) of the actuator. Based on the position of the actuator, the apparatus 100 modifies the musical signals. The actuator and sensor do not physically contact each other during operation of the switch 150. Thus, the apparatus 100 can provide for a more reliable switch design that is slower to wear down than conventional mechanical switch designs, and as such, the apparatus 100 may have a longer operational lifespan than conventional effects units.

In some embodiments, the switch 150 may include a switch body 151 that mounts the switch 150 to the housing 102. The switch body 151 may be configured to mount the switch 150 such that the switch 150 extends outwardly from an upper surface 102a of the housing 102. The switch 150 may be positioned so that a user can easily access the switch 150. For example, the switch 150 may be configured so that a user can access the switch with their foot while playing a musical instrument. The switch body 151 may hold the switch 150 in place such that the actuator can move linearly along an axis 103 that extends perpendicularly to the upper surface 102a of the housing 102 and rotationally around the axis 103. The switch 150 may be operated by a user to control various functions of the apparatus 100. The switch 150 may be oriented such that the axis 103 is the centerline of the switch 150. In some embodiments, the switch 150 may be pushed (also referred to herein as “pressed”) by the user such that the actuator translates linearly along the axis 103. In some embodiments, the switch 150 may be rotated (also referred to herein as “turned”) by the user such that the actuator rotates about the same axis 103. The switch 150 may be simultaneously pushed and turned. In some embodiments, the switch 150 is configured to be operated by a hand and/or a foot of the user. In some embodiments, the switch 150 can be used to adjust the modification of the musical signals (e.g., pushing the switch 150 may turn on/off the modification).

In some embodiments, the apparatus 100 may include a housing 102. The housing 102 may be a case that houses and/or supports the components of the apparatus 100. The housing 102 may include an externally facing surface 102a on which one or more of the displays 104a and 104b, the switch 150, and the switch body 151 may be positioned.

In some embodiments, the apparatus 100 may include one or more displays, including a main display 104a and a switch display 104b, each of which may be a screen or panel for displaying icons, images, text, and/or other visual indicators related to the apparatus 100. The main display 104a may display information relating to the apparatus 100 as a whole, including information from all of the switches, whereas the switch display 104b may display information specifically pertaining to its corresponding switch (e.g., switch 150). The displays 104a and 104b may be electronically connected to one or more of the input 105a, the output 105b, the switch 150, and any other electronic components of the apparatus 100 (e.g., processors and lights).

In some embodiments, the main display 104a may provide information about the settings of the apparatus 100, a mode of the apparatus 100 (e.g., whether the apparatus 100 is in an “editing” mode in which its settings can be changed), which switches are active, and/or what modifications are being performed on the musical signals. In some embodiments, the main display 104a may display a visual representation of the musical signals (e.g., a waveform). The main display 104a may be a larger display than the switch display 104b.

In some embodiments, the switch display 104b may provide information about the settings of the switch 150, and/or whether the switch 150 is activated or deactivated. In some embodiments, the switch display 104b may display one or more values associated with the modification of the musical signals. In some embodiments, the switch display 104b may display one or more values associated with a setting of the switch 150. The switch display 104b may be positioned adjacent to its corresponding switch 150.

In some embodiments, the apparatus 100 may include at least one input 105a, which may include at least one input jack or other type of connector for receiving a musical signal. The musical signal may be a digital signal or an analog signal. Different inputs 105a may receive different types of signals. For example, a type of input may be configured to receive analog signals and a second type of input may be configured to receive digital signals. The apparatus 100 may also include at least one output 105b, which may include at least one output jack or other type of connector for connecting an output device. For example, the output 105b may be configured to output the modified musical signal to a speaker. The input 105a and output 105b may be positioned in any suitable location, including on a side of the housing 102, as shown, and/or at a rear panel (not shown) of the housing. The input 105a and output 105b may have any standard jack configuration.

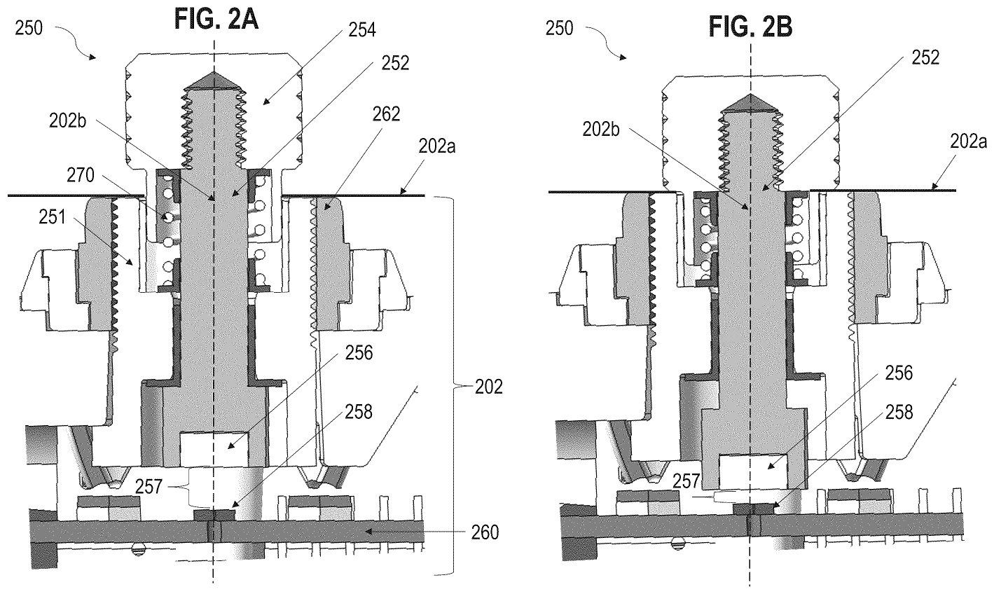

FIGS. 2A and 2B illustrate cross-sectional views of an exemplary switch 250 of an apparatus for modifying musical signals (e.g., apparatus 100 of FIG. 1). Switch 250 can be used for any of the switches 150 of FIG. 1. In some embodiments, the functionality of the switch 250 may be determined by its translational position and/or its rotational position.

FIG. 2A illustrates the switch 250 in a first position, and FIG. 2B illustrates the switch 250 after an actuator 252 of the switch 250 has been linearly translated relative to the first position, into a second position. The switch 250 may be oriented such that an axis 203 running along the centerline of the switch 250 is orthogonal to a surface 202a of the housing 202. In some embodiments, the switch 250 may include a switch body 251 configured to attach to the housing 202. The actuator 252 may be disposed at least partially within the switch body 251. The switch body 251 may be a ring-shaped component attached to the housing 202 and configured to support the actuator 252 along a circumference of the actuator 252. The actuator 252 may be a rod-shaped component configured to move linearly (i.e., along the axis 203) through the switch body 251 and rotationally (i.e., about the axis 203) within the switch body 251. The switch 250 may have any of the features of the switch 150 of FIG. 1, and the switch body 251 may have any of the features of the switch body 151 of FIG. 1.

In some embodiments, the actuator 252 may include a cap 254. The cap 254 may be a dial or knob mounted to a first end of the actuator 252. The cap 254 may provide an accessible, appropriately sized surface for a human user to touch. The cap 254 may be touched by the user to move the actuator 252. For example, the user may press and/or push the cap 254 to move the actuator 252 linearly, and rotate and/or turn the cap 254 to move the actuator 252 rotationally. The cap 254 may be removably attached to the actuator 252. In some embodiments, the actuator 252 can be moved directly by the user without the cap 254.

In some embodiments, the actuator 252 may include a second end 256. The second end 256 opposite to the first end (i.e., on the other side of the actuator 252 from the cap 254). The sensor 258 may measure the position of the actuator 252 based on the position of the second end 256 without making contact with the actuator 252.

The second end 256 may comprise any device or material that enables the sensor 258 to contactlessly detect the position of the second end 256 and thus the position of the actuator 252. In some embodiments, the sensor 258 is a magnetic field sensor, and the second end 256 comprises a magnet. The magnetic field sensor 258 may detect the magnetic field characteristics of the magnet to determine the position of the second end 256. The magnet may be made of ferromagnetic materials, such as one or more of iron, cobalt, nickel, neodymium, and alloys thereof. The magnet may be diametrically magnetized such that the rotation of the actuator 252 about the axis 203 rotates the magnetic field associated with the magnet. In some embodiments, the magnet may be an electromagnet. In some embodiments, the magnet may be cylindrical in shape. In some embodiments, the sensor 258 is an optical sensor that emits light toward and receives reflected light from the second end 256 to determine the position of the second end 256. In some embodiments, the sensor 258 is an AC induction sensor, and the second end 256 may comprise an electromagnetic coil. The AC induction sensor 258 may detect the characteristics of the electromagnetic coil's field to determine the position of the second end 256.

In some embodiments, a sensor 258 may be mounted to a processor board 260 beneath the second end 256 such that the sensor 258 can measure the position of the second end 256. The sensor 258 may be capable of contactlessly sensing and measuring the position of the second end 256. In some embodiments, the sensor 258 may be capable of detecting relative changes in the angular position of the second end 256 (e.g., based on the direction of the magnetic field) relative to a previous angular position. In some embodiments, the sensor 258 may be capable of detecting absolute changes in the angular position of the second end 256 relative to a preset angular position. In some embodiments, the sensor 258 may be programmable (e.g., via the processor board 260). In some embodiments, the sensor is configured to output an angular position reading that corresponds to an angular position of the actuator 252 to the processor board 260.

In some embodiments, the translation of the actuator 252 along the axis 203 may increase or decrease a distance 257 between the second end 256 and the sensor 258. For example, in FIG. 2A, the switch 250 is not pressed (i.e., it is in a first translational position). In FIG. 2B, the switch 250 is in a pressed (i.e., in a second translational position) in which the distance 257 between the second end 256 and the sensor 258 has decreased relative to the distance 257 of FIG. 2A (e.g., from 3 mm to 1 mm).

In some embodiments, a predetermined threshold value may be used in conjunction with the distance 257 to determine the “state” of the switch 250. In some embodiments, any distance 257 larger than the predetermined threshold value can be defined as “state 1.” In some embodiments, any distance 257 smaller than a predetermined threshold value (e.g., 2 mm) can be defined as “state 2.” In some embodiments, the processor board 260 may be configured to determine the threshold value above which the switch 250 is in the first state, and below which the switch 250 is in the second state. When the switch 250 changes between the “up” position and the “down” position, the movement of second end 256 between “state 1” and “state 2” can be sensed by sensor 258 when the predetermined threshold value is passed in either direction. This operation may be repeated indefinitely by the user. In the embodiment described above, two switch states are used as example. It would be possible to have a finer permutation of states, such as two thresholds which creates three different states, etc.

In some embodiments, the second end 256 does not make physical contact with the sensor 258. As shown in FIG. 2B, the cap 254 makes contact with the surface 202a of the housing 202, which prevents the switch 250 from being pressed down further. Accordingly, the position of the actuator 252 as depicted in FIG. 2B may be the lowest translational position to which the actuator 252 can be pushed. In some embodiments, the apparatus can modify the musical signals based on the distance 257 between the second end 256 and the sensor 258, as calculated by the processor board 260 based on the position measurements of the sensor 258.

In some embodiments, a spring 270 may be positioned between the cap 254 and the housing 202 such that the spring 270 is compressed when the cap 254 is pressed (which translates the actuator 252 and its second end 256 at the same time). Due to rebound force, the spring 270 may return the switch to the “up” position after pressing. For example, in some embodiments, when a user presses the switch 250 into the second position, the spring 270 is compressed. When the user releases the switch 250, it may return to the first position due to forces provided, at least in part, by the compression of the spring 270 being undone. During the push down operation, the distance 257 between the second end 256 and the sensor 258 decreases, while during the spring back operation, the distance 257 between the second end 256 and the sensor 258 increases.

Referring back to FIG. 2A, in some embodiments, the processor board 260 may be a PCB that includes at least one processor. The processor board 260 may be configured to modify the musical signal based on the translational position of the actuator 252 along the axis 203 relative to a threshold translational position (e.g., when the distance 257 between the second end 256 and the sensor 258 is greater than or less than a threshold value, such as 2 mm). For example, when the switch 250 is in the first position (i.e., distance 257 is greater than the threshold distance value, and/or the magnetic field intensity is less than the threshold intensity value), the processor board 260 may turn the switch to an “on” mode, enabling all normal functions of the switch 250 (i.e., activating the switch 250). If the switch 250 is set to increase the reverberation of the musical signal, the effect may be applied to the musical signal so long as the switch 250 remains “on.” However, when the switch 250 is in the second position (i.e., distance 257 is less than the threshold distance value, and/or the magnetic field intensity is greater than the threshold intensity value), the processor board 260 may turn the switch 250 to an “off” mode, disabling at least one of the normal functions of the switch 250 (i.e., deactivating the switch 250). The reverberation effect may not be applied to the musical signal until the switch 250 is turned “on” again.

In some embodiments, the processor board 260 may be configured to adjust a degree of the musical signal modification, such that a larger determined value (e.g., a larger field intensity reading from the sensor 258, indicating that the second end 256 has been pressed down closer to the sensor 258) corresponds to a larger degree of the modification (e.g., increasing the amplitude of the musical signal by a larger amount).

In some embodiments, the light pipe 262 may be a translucent component configured to produce and scatter visible light. In some embodiments, the light pipe 262 may comprise one or more red-green-blue LEDs that can be adjusted to change brightness, color, and/or blinking. The light pipe 262 may be positioned at least partially around the actuator 252 (e.g., adjacent to the switch body 251). In some embodiments, the light pipe 262 may produce an unbroken ring of light.

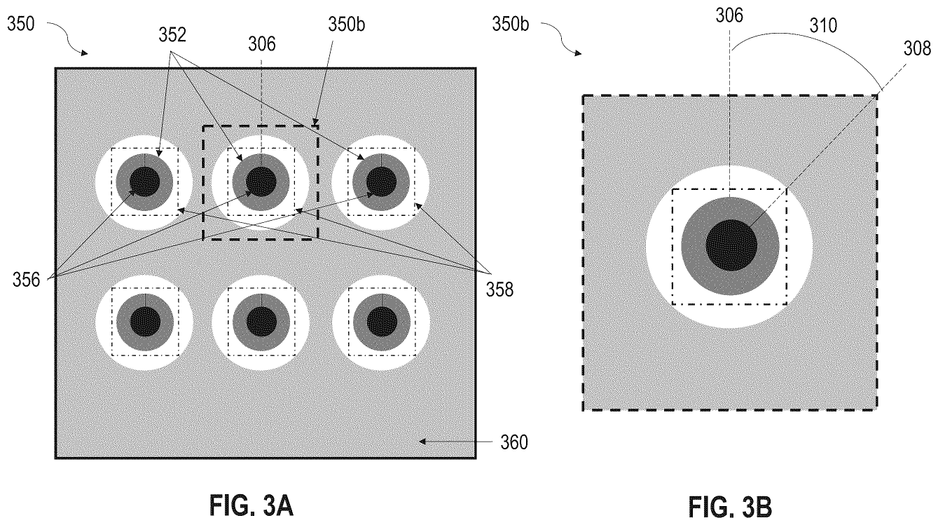

FIGS. 3A and 3B illustrate top-down views of an exemplary processor board 360 of an apparatus (e.g., apparatus 100 of FIG. 1) for modifying musical signals based on the rotation of a plurality of switches 350. Specifically, the processor board 360 may be configured to modify the musical signals based on the angular positions of one or more switches of the plurality of switches 350. The switches 350 may comprise a plurality of actuators 352 with second ends 356 and a plurality of sensors 358 configured to detect changes in the positions of the second ends 356. Based on the detected changes, the angle change 310 of each actuator can be determined by the processor board 360. The angle change 310 may represent the relative difference in angle between a first angular position 306 and a second angular position 308. Based on the angle change 310, the processor board 360 may apply different modifications and/or degrees of modification to the musical signals.

FIG. 3A illustrates a plurality of switches 350 in a first angular position 306, and FIG. 3B illustrates a switch 350b of the plurality of switches 350 after it has been rotated relative to the first angular position 306. As shown in FIG. 3A, the plurality of switches 350 may include a plurality of actuators 352 (with second ends 356) positioned above a processor board 360. Each switch of the plurality of switches 350 may comprise a switch body (e.g., switch body 151 of FIG. 1) and a sensor mounted to the processor board 360 mounted beneath the switch bodies. For example, a plurality of sensors 358 may be mounted to the same processor board 360. The plurality of sensors 358 may be positioned such that they are aligned beneath the plurality of second ends 356. The sensors 358 may be configured to contactlessly detect the second ends 356 and generate measurements corresponding to the linear and/or angular positions of the second ends 356. For example, if the second ends 356 comprise magnets, the sensors 358 may be configured to detect changes in the directions of the magnetic fields of the magnets. Based on the detected changes in the magnetic fields' directions, the angular position of each switch of the plurality of switches 350 can be determined by one or both of the sensors 358 and the processor board 360.

In some embodiments, each switch (e.g., switch 350b) of the plurality of switches 350 may include an actuator 352. As the actuator 352 is rotated, the second end 356 may rotate with it. In FIG. 3A, an arbitrary reference angular position, the first angular position 306, is shown for illustrative purposes. In FIG. 3B, the actuator 352 has been rotated such that the second end 356 is now aligned with a second angular position 308. The angle change 310 is the difference between the first angular position 306 and the second angular position 308. The switch 350 can be rotated such that the angle change 310 is anywhere between 0-360 degrees. In some embodiments, the switch 350 can be rotated more than 360 degrees, e.g., infinitely in any direction.

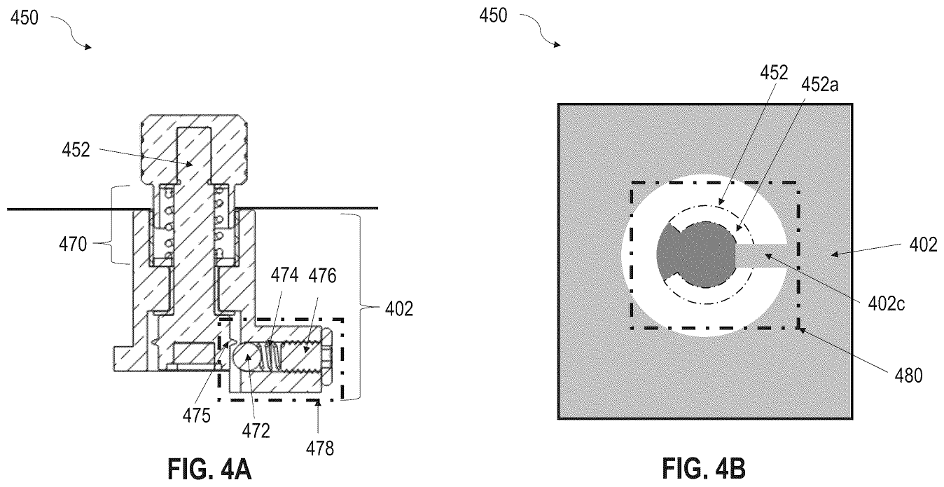

FIG. 4A illustrates a cross-sectional view of an exemplary switch 450 having a detent mechanism 478 configured to provide tactile and/or auditory feedback to the user of when the switch 450 has been pressed into its second position. The feedback provided by the detent mechanism 478 may allow the user to detect when the switch 450 has been pressed without visually monitoring the switch 450. For example, during a live performance, the user may operate the switch 450 by foot without interrupting the flow of the performance by looking down at the switch 450.

In some embodiments, the detent mechanism 478 may include a ball 472, a ball spring 474, a projection 475, and a tension screw 476. The ball stopper 475 may be an annular ring with a triangular ramp profile that is positioned around and/or protruding from the actuator 452. When the actuator 452 is pressed down (e.g., vertically with respect to the view shown in FIG. 4A) by a user, the ball stopper 475 may contact the ball 472, push it away from the actuator 452 (e.g., horizontally with respect to the view shown in FIG. 4A) against a ball spring 474, which may be compressed and apply a return force to the ball 472. As the user continues to press the actuator 452, the projection 475 will continue to move downward, eventually clearing the ball 472. Under action of the ball spring 474, the ball 472 will return and impact the actuator 452. The impact of the ball 472 against the actuator 452 may produce a “click” sound and/or provide tactile feedback to the user. The tension screw 476 may be used to adjust the spring force of the ball spring 474 by adjusting its compression, thereby increasing or decreasing the volume of the sound and/or the strength of the tactile feedback. In some embodiments, the detent mechanism 478 may be implemented with a leaf spring (e.g., as ball spring 474) or other form of spring. In some embodiments, the switch 450 may have more than one detent mechanism 478 per switch 450. In some embodiments, the detent mechanism 478 may be positioned within and/or supported by the housing 402.

In some embodiments, the detent mechanism 478 may be configured to provide tactile and/or auditory feedback when the user rotates and/or turns the switch 450, causing the actuator 452 to undergo rotational movement. The actuator 452 may have one or more vertical grooves extending at least partially along the circumference of the actuator 452. When the actuator 452 is rotated, the ball 472 may switch between making contact with the peaks and valleys of the one or more vertical grooves. The impact of the ball 472 against the rotating components of the actuator 452 may produce a sound and/or provide tactile feedback to the user.

FIG. 4B illustrates a top-down view of an exemplary switch 450 having a rotational limiter mechanism 480. For example, as shown in FIG. 4B, the rotational limiter mechanism 480 is configured to restrict the rotational motion of the actuator 452 to a limited range of angles when the user rotates and/or turns the switch 450. Physically limiting the rotational motion of the actuator 452 in such a manner may allow the actuator 452 to be rotated between the furthest position in either direction without exceeding the desired range of motion (e.g., 270-300 degrees of rotation).

In some embodiments, the rotational limiter mechanism 480 may include a peg 402c protruding from the housing 402 (or any components attached to the housing 402) toward a slot 452a recessed into the actuator 452 (or any components attached to the actuator 452) and configured to receive the peg 402c. In some embodiments, the peg 402c may instead protrude from the actuator 452 (or any components attached to the actuator 452), and the slot 452a may instead be recessed into the housing 402 (or any components attached to the housing 402). The actuator 452 may be rotated until the peg 402c makes contact with one or more sides of the slot 452a, thereby stopping the actuator 452 from rotating further in that direction. In some embodiments, the switch 450 may have more than one rotational limiter mechanism 480 per switch 450.

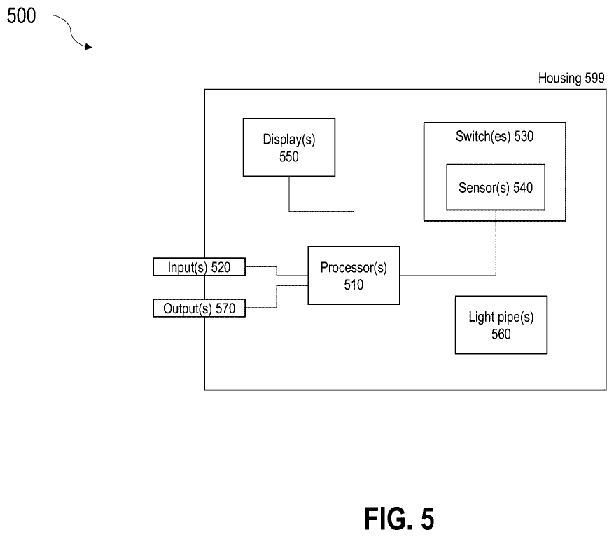

FIG. 5 illustrates a block diagram of an exemplary apparatus 500 for modifying musical signals. The apparatus 500 may be configured to receive musical signal from input(s) 520, receive user inputs from the switch(es) 530 based on the measurements of the sensor(s) 540, modify the musical signals using the processor(s) 510 based on the user inputs, and output the modified signals to a speaker using the output(s) 570.

In some embodiments, the switch(es) 530 can be simultaneously pressed and rotated to modify the musical signals. For example, the switch(es) 530 can be pressed to adjust a first attribute of the musical signals (e.g., amplitude), and rotated to adjust a second attribute of the musical signals (e.g., pitch). In some embodiments, the switch(es) 530 can be pressed to switch between operating mode of the apparatus (e.g., playing mode and editing mode) and simultaneously rotated to adjust an attribute of the musical signals (e.g., reverberation), and vice versa. In some embodiments, the combination of pressing and rotating the switch(es) 530 may produce a different modification to the musical signals than those produced when independently pressing and independently rotating the switch(es) 530. In some embodiments, the combination of pressing and rotating may enable the user to access additional features, such as a “deep editing mode” for editing settings associated with the apparatus. The switch(es) 530 can have any features of the switch 150 of FIG. 1, the switch 250 of FIGS. 2A and 2B, the plurality of switches 350 of FIG. 3A, the switch 350b of FIG. 3B, and/or the switches 450 of FIGS. 4A and 4B.

In some embodiments, the exemplary apparatus 500 can include one or more processor(s) 510 configured to receive data from and/or transmit instructions to all of its connected components. The processor(s) 510 may be configured to perform any calculations needed to convert the measurements of the sensor(s) 540 into translational and/or angular position data associated with the switch(es) 530. The processor(s) 510 can then modify the musical signal based on the position data. For example, in some embodiments, the processor(s) 510 can modify the musical signals based on at least one of: the angular position of an actuator and/or a magnet of the switch(es) 530 relative to an angular threshold position, an angle change between any two angular positions, a rate of rotation of the actuator and/or the magnet of the switch(es) 530, and an angular acceleration of the actuator and/or the magnet of the switch(es) 530. In some embodiments, the sensor(s) 540 may be configured to convert the magnetic field measurements into position data, and the processor(s) 510 may be configured to receive the position data directly.

In some embodiments, the processor(s) 510 may be configured to convert the magnetic field measurements of the sensor(s) 540 into translational position data pertaining to the location of the switch(es) 530 along the axis of motion (e.g., axis 103 of FIG. 1). For example, based on the magnitude of the magnetic field measurements, the processor(s) 510 can calculate the absolute translational position of the switch(es) 530, the change in distance between two translational positions, the translational speed along the axis, and/or the translational acceleration along the axis.

In some embodiments, the processor(s) 510 may be configured to convert the magnetic field measurements of the sensor(s) 540 into angular position data pertaining to the rotation of the switch(es) 530 about the axis of motion (e.g., axis 103 of FIG. 1). For example, based on the direction of the magnetic field measurements, the processor(s) 510 can calculate the absolute and/or relative angular positions of the switch(es) 530, the angular speed about the axis, and/or the angular acceleration about the axis. In some embodiments, the processor(s) 510 may be configured to identify a resolution of the rotation. The processor(s) 510 may change the resolution of the rotation from a higher resolution to a lower resolution and vice versa. In some embodiments, the resolution of the rotation angle may be changed based on the calculated angular speed and/or acceleration of the switch(es) 530. For example, a user may rotate the switch(es) 530 quickly to scroll through many resolutions at high speed, then slow down or stop rotating to fine tune the scrolling.

In some embodiments, the processor(s) 510 may be configured to define one or more threshold values for each switch of the switch(es) 530. For example, the processor(s) 510 can be used to set a translational and/or rotational threshold value, then can be used to detect when the location or rotation of the switch(es) 530 crosses the threshold). In some embodiments, the processor(s) 510 can define the operating modes of the apparatus 500 based on the one or more threshold values of the switch(es) 530. For example, when the switch(es) 530 are not pressed (e.g., above a translational threshold value), the apparatus 500 may be in “playing mode.” Once the switch(es) 530 are pressed down (e.g., below a translational threshold value), the apparatus 500 may enter “editing mode”).

In some embodiments, the processor(s) 510 may be configured to define, receive, calculate, and/or change the following variables from the connected light pipe(s) 560: LED color, LED brightness, and/or LED blink rate. In some embodiments, the light pipe may have a single color. In some embodiments, the light pipe may have various colors and/or changing colors across different regions of the light pipe. The LEDs of the light pipe may be electronically controlled by the processor(s) 510.

In some embodiments, the apparatus 500 may include a housing 599. The components of the apparatus 500 may be housed at least partially within the housing 599. The components of the apparatus 500 can have any features of the corresponding components of FIG. 1, FIGS. 2A and 2B, FIGS. 3A and 3B, and/or FIGS. 4A and 4B.

In some embodiments, the processor(s) 510 may not be physically connected to the apparatus 500. Instead, the apparatus 500 may be a device for wirelessly transmitting information (functioning akin to a remote control) that instructs an external device to perform one or more functions. The content of the wireless transmissions may be determined based on the measurements of the sensor(s) 540. For example, pressing the switch(es) 530 may change the linear position measurements generated by the sensor(s) 540. This may instruct an external device, such as a speaker or amplifier, to activate or deactivate a sound modulation effect. In such embodiments, the apparatus 500 may not directly receive a musical signal and, accordingly, may not include an input jack and/or output jack. Instead, the external device may receive the musical signal and modify it according to the wireless transmissions of the apparatus 500.

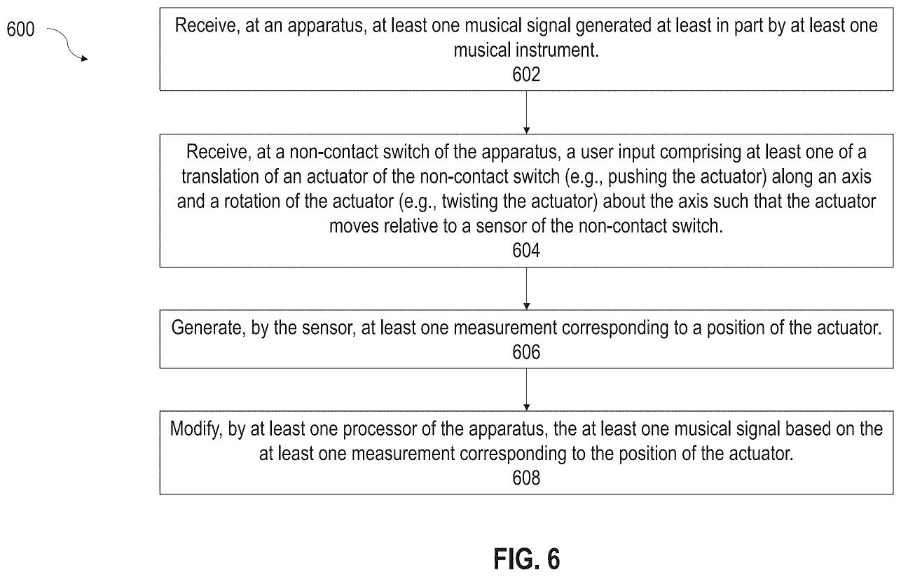

FIG. 6 illustrates a flowchart of an exemplary method 600 for modifying musical signals. The method 600 may be performed using an apparatus for modifying musical signals, such as the exemplary apparatus 100.

At step 602, the apparatus receives at least one musical signal generated at least in part by at least one musical instrument. The apparatus can include any features of apparatus 100 of FIG. 1 and/or apparatus 500 of FIG. 5.

At step 604, a non-contact switch of the apparatus receives a user input comprising at least one of a translation of an actuator of the switch along an axis (e.g., the user pushes and/or presses the actuator) and a rotation of the actuator about the axis (e.g., the user rotates and/or turns the actuator). The user input may cause the actuator of the switch to move relative to a sensor of the switch. The switch can include any features of switch 150 of FIG. 1, the switch 250 of FIGS. 2A and 2B, the plurality of switches 350 of FIG. 3A, the switch 350b of FIG. 3B, the switches 450 of FIGS. 4A and 4B, and/or the switch(es) 530 of FIG. 5.

At step 606, the sensor contactlessly generates at least one measurement corresponding to a position of the actuator. For example, if the actuator includes a magnet and the sensor includes a magnetic field sensor, the sensor may detect the magnetic field characteristics associated with the magnet to generate a position measurement for the actuator. The movement of the magnet described in step 604 may alter the location of its magnetic field in a manner that can be measured by the sensor.

At step 608, at least one processor of the apparatus modifies the at least one musical signal based on the position measurement from step 606. In some embodiments, a change in the rotational position of the actuator may be associated with a change in the modification characteristics. In some embodiments, a change in the linear position of the actuator may be associated with the activation/deactivation of the modification. In some embodiments, closer actuator positions may be associated with modifications of a first extreme (e.g., higher pitch, louder sound, and/or greater distortion), and farther actuator positions may be associated with modifications of a second extreme (e.g., lower pitch, quieter sound, and/or less distortion), and vice versa. The at least one processor can include any features of processor 260 of FIGS. 2A and 2B and/or processor(s) 510 of FIG. 5.

In some embodiments, modifying the at least one musical signal comprises setting at least one parameter based on the measurement corresponding to the position of the actuator, then modifying the at least one musical signal based on the at least one parameter. For example, the at least one parameter may be a quality of the musical signal, such as pitch, amplitude, distortion, modulation, reverberation, delay, and/or repetition. In some embodiments, the at least one parameter may be set in an editing mode (i.e., a first mode), and the at least one musical signal may be modified in a playing mode (i.e., a second mode). During the playing mode, a first type of user input (e.g., turning the switch and thereby rotating the actuator) may not change the at least one parameter that was set in the editing mode. However, a second type of user input (e.g., pressing the switch and thereby translating the actuator) may change the at least one parameter. For example, before a concert, a musician can select the “editing mode” and pre-set “reverberation” as the quality of the musical signal that will be modified. During “editing mode,” the musician may rotate the switch to change a value of a parameter that can be modified during “playing mode.” Multiple switches may be used to adjust multiple parameters. Once the concert begins, the musician can enter the “playing mode” and begin playing an instrument. The musician can press down on the switch to activate or deactivate the “reverberation” effect. However, during “playing mode,” if the musician rotates the switch, the parameter will not change from “reverberation” because the rotational input does not affect the modification of the sound. This optional feature may prevent unintended user inputs from modifying the musical signal in unintended ways. In some embodiments, modifying the at least one musical signal may comprise producing one or more special effects, such as overdrive, fuzz, wah, delay, buffer, chorus, flanger, phaser, tremolo, looper, compressor, octave, equalization, noise gate, acoustic, tuner, boost, pitch change, amplitude change, distortion, modulation, reverberation, delay, and/or repetition.

In some embodiments, the apparatus may include multiple switches, and individual switches can be activated or deactivated to adjust the modification of the musical signal. In some embodiments, based on the parameter of the musical signal to be modified (i.e., the special effects), one or more switches can be activated or deactivated. For example, the apparatus may be configured to emulate “Amp X” which has a “reverberation” effect and contains four knobs for receiving user inputs. Accordingly, four switches of the apparatus may be activated (e.g., the switches modify the musical signal based on the user input), and the other switches may be deactivated (e.g., the switches have no effect on the musical signal). The switch display corresponding to each switch may indicate whether the switch is activated or deactivated, and/or which effect each switch is associated with.

In some embodiments, a switch may be configured to perform functionalities beyond modifying a signal from a musical instrument. For example, the switch may be configured to bank up/down, initiate a metronome feature (e.g., playing a tempo/rhythm as audio), or perform other functionalities, musical or non-musical.

In some embodiments, instead of the digital systems described herein, the apparatus may function as an analog system. For example, the switch of such an apparatus may include a non-contact proximity-based sensor that generates a continuous electrical signal when pressed. Based on the amplitude and/or frequency of the electrical signal, the apparatus may modify a musical signal or perform another functionality. In some embodiments, the analog system may have no processors.

This application discloses several numerical ranges in the text and figures. The numerical ranges disclosed inherently support any range or value within the disclosed numerical ranges, including the endpoints, even though a precise range limitation is not stated verbatim in the specification because this disclosure can be practiced throughout the disclosed numerical ranges.

Because the apparatus (e.g., apparatus 100 of FIG. 1) may be operated by a human user's foot, it may be necessary for the housing to be able to withstand forces generated by a human standing and/or stepping on the housing. For example, the housing may be configured to withstand a static load weighing between, e.g., 1 to 1000 pounds. The housing may withstand up to 100 pounds, 200 pounds, 300 pounds, 400 pounds, 500 pounds, 600 pounds, 700 pounds, 800 pounds, 900 pounds, and/or 1000 pounds. The housing may withstand at least or equal to 1 pound, 10 pounds, 50 pounds, 100 pounds, 200 pounds, 300 pounds, 400 pounds, 500 pounds, 600 pounds, 700 pounds, 800 pounds, 900 pounds, and/or 1000 pounds.

In some embodiments, the sensor (e.g., sensor 258 of FIGS. 2A and 2B) may be configured to operate under a variety of conditions and receive power in a variety of configurations. For example, the sensor may be configured to operate within a temperature range of −40 to 125 degrees Celsius (e.g., 25 degrees Celsius), a voltage range of 1 V to 10 V (e.g., 3.3 V), and a current range of 1 mA to 20 mA (e.g., 12 mA).

In some embodiments, the switch (e.g., switch 150 of FIG. 1) may be able to withstand, e.g., at least 1 million presses during its operational lifetime. The switch may withstand at least 1,000 presses, 5,000 presses, 10,000 presses, 20,000 presses, 30,000 presses, 40,000 presses, 50,000 presses, 60,000 presses, 70,000 presses, 80,000 presses, 90,000 presses, 100,000 presses, 200,000 presses, 300,000 presses, 400,000 presses, 500,000 presses, 600,000 presses, 700,000 presses, 800,000 presses, 900,000 presses, and/or 1 million presses during its operational lifetime. For each press, between, e.g., 0.01 kgf and 100 kgf may be applied to the switch. Up to 0.1 kgf, 0.5 kgf, 1 kgf, 5 kgf, 10 kgf, 20 kgf, 30 kgf, 40 kgf, 50 kgf, 60 kgf, 70 kgf, 80 kgf, 90 kgf, and/or 100 kgf may be applied to the switch. At least or equal to 0.01 kgf, 0.1 kgf, 0.5 kgf, 1 kgf, 5 kgf, 10 kgf, 20 kgf, 30 kgf, 40 kgf, 50 kgf, 60 kgf, 70 kgf, 80 kgf, 90 kgf, and/or 100 kgf may be applied to the switch. The switch may be able to withstand, e.g., at least 1 million rotations during its operational lifetime. The switch may withstand at least 1,000 rotations, 5,000 rotations, 10,000 rotations, 20,000 rotations, 30,000 rotations, 40,000 rotations, 50,000 rotations, 60,000 rotations, 70,000 rotations, 80,000 rotations, 90,000 rotations, 100,000 rotations, 200,000 rotations, 300,000 rotations, 400,000 rotations, 500,000 rotations, 600,000 rotations, 700,000 rotations, 800,000 rotations, 900,000 rotations, and/or 1 million rotations during its operational lifetime.

In some embodiments, the distance (e.g., distance 257 of FIGS. 2A and 2B) between the first position and the second position of the switch may range from, e.g., 0.1 mm to 10 mm in length. The distance may be a value up to 0.5 mm, 1 mm, 2 mm, 3 mm, 4 mm, 5 mm, 6 mm, 7 mm, 8 mm, 9 mm, and/or 10 mm. The distance may be a value at least or equal to 0.1 mm, 0.5 mm, 1 mm, 2 mm, 3 mm, 4 mm, 5 mm, 6 mm, 7 mm, 8 mm, and/or 9 mm.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. An apparatus for modifying at least one musical signal, the apparatus comprising:
a housing;
at least one input for receiving at least one musical signal generated at least in part by at least one musical instrument;
at least one processor for modifying the at least one musical signal; and
at least one non-contact switch mounted to the housing such that a user can interact with the at least one non-contact switch to adjust the modification of the at least one musical signal, the at least one non-contact switch comprising:
an actuator configured to rotate about an axis and translate along the axis, and
a sensor configured to generate at least one measurement corresponding to a position of the actuator,
wherein the at least one processor is configured to modify the at least one musical signal based on the measurement corresponding to the position of the actuator.

2. The apparatus of claim 1, wherein the sensor comprises a magnetic sensor, an optical sensor, or an AC induction sensor.

3. The apparatus of claim 2, wherein the sensor comprises a magnetic field sensor and the actuator comprises a magnet.

4. The apparatus of claim 3, wherein the magnet is diametrically magnetized such that the rotation of the actuator about the axis changes a direction of the magnetic field associated with the magnet.

5. The apparatus of claim 1, wherein the position comprises one or both of a translational position and an angular position.

6. The apparatus of claim 5, wherein the at least one measurement comprises a measurement of the translational position and a measurement of the angular position.

7. The apparatus of claim 1, wherein the at least one non-contact switch comprises multiple non-contact switches, each non-contact switch comprising a switch body mounted to a housing of the apparatus and a sensor mounted to a PCB mounted beneath the switch bodies, such that multiple sensors are mounted to the same PCB.

8. The apparatus of claim 1, wherein the at least one non-contact switch comprises multiple non-contact switches for modifying multiple attributes of the at least one musical signal.

9. The apparatus of claim 1, wherein the at least one processor is configured to modify the at least one musical signal based on at least one of:
a translational position of the actuator along the axis relative to at least one translational threshold,
a translational speed of the actuator along the axis,
a translational acceleration of the actuator along the axis,
an angular position of the actuator about the axis relative to at least one angular threshold,
a change in angle of the actuator about the axis,
a rate of rotation of the actuator about the axis, and
an angular acceleration of the actuator about the axis.

10. The apparatus of claim 1, wherein the translation of the actuator along the axis changes a distance between the actuator and the sensor.

11. The apparatus of claim 1, wherein the at least one non-contact switch further comprises a light pipe surrounding at least a portion of the actuator.

12. The apparatus of claim 1, wherein the at least one non-contact switch further comprises at least one detent mechanism configured to provide tactile feedback to the user during one or both of the rotation of the actuator about the axis and the translation of the actuator along the axis.

13. The apparatus of claim 1, wherein the at least one non-contact switch further comprises at least one limiter configured to restrict the rotation of the actuator to a predetermined range of angles.

14. The apparatus of claim 1, wherein the at least one processor is configured to change a mode of operation of the apparatus, wherein in a first mode, the at least one processor is configured to set at least one parameter based on the at least one measurement, and in a second mode, the at least one processor is configured to modify the at least one musical signal based on the at least one parameter.

15. A method for modifying at least one musical signal, the method comprising:
receiving, at an apparatus, at least one musical signal generated at least in part by at least one musical instrument;
receiving, at a non-contact switch of the apparatus, a user input comprising at least one of a translation of an actuator of the non-contact switch along an axis and a rotation of the actuator about the axis such that the actuator of the non-contact switch moves relative to a sensor of the non-contact switch;
generating, by the sensor, at least one measurement corresponding to a position of the actuator; and
modifying, by at least one processor of the apparatus, the at least one musical signal based on the at least one measurement corresponding to the position of the actuator.

16. The method of claim 15, wherein modifying the at least one musical signal comprises setting at least one parameter based on the at least one measurement and modifying the at least one musical signal based on the at least one parameter.

17. The method of claim 16, wherein the at least one parameter is set in a first mode and the at least one musical signal is modified in a second mode.

18. The method of claim 17, wherein, during the second mode, a first user input to the non-contact switch does not change the at least one parameter of the apparatus.

19. The method of claim 18, wherein the first user input to the non-contact switch is the rotation of the actuator.

20. The method of claim 17, wherein, during the second mode, a second user input to the non-contact switch changes the at least one parameter of the apparatus.

21. The method of claim 20, wherein the second user input to the non-contact switch is the translation of the actuator.

22. The method of claim 15, wherein modifying the at least one musical signal comprises producing one or more special effects including one or more of: overdrive, fuzz, wah, delay, buffer, chorus, flanger, phaser, tremolo, looper, compressor, octave, equalization, noise gate, acoustic, tuner, boost, pitch change, amplitude change, distortion, modulation, reverberation, delay, and repetition.
